(19) United States
(12) Patent Application Publication
(10) Pub. No.: US 2022/0044916 A1
(43) Pub. Date: Feb. 10, 2022

(54) SUBSTRATE PROCESSING APPARATUS

(71) Applicant: ASM IP Holding B.V., Almere (NL)

(72) Inventors: KiChul Um, Osan-si (KR); SangJean Jeon, Suwon-si (KR); DooHan Kim, Hwaseong-si (KR); SangYeop Lee, Hwaseong-si (KR)

(21) Appl. No.: 17/392,257

(22) Filed: Aug. 3, 2021

Related U.S. Application Data
(60) Provisional application No. 63/062,285, filed on Aug. 6, 2020.

(51) Int. Cl. H01J 37/32

(52) U.S. Cl. CPC H01J 37/32715; H01J 37/3255; H01J 37/32541

(57) ABSTRACT

A substrate processing apparatus capable of preventing an increase in resistance of a lower electrode due to thermal deformation includes: an electrode; and a rod contacting the electrode, wherein the rod includes a first portion having a first coefficient of thermal expansion; and a second portion having a second coefficient of thermal expansion that is less than the first coefficient of thermal expansion.

### CROSS-REFERENCE TO RELATED APPLICATIONS

This application claims priority to U.S. Application No. 63/062,285, filed on Aug. 6, 2020 in the United States Patent and Trademark Office, the disclosure of which is incorporated herein in its entirety by reference.

### BACKGROUND

### 1. Field

One or more embodiments relate to a substrate processing apparatus, and more particularly, to a substrate processing apparatus including a substrate support unit.

### 2. Description of the Related Art

A process using plasma, for example, a plasma chemical vapor deposition (PECVD) or plasma atomic layer deposition (PEALD) process, may be achieved by introducing a source gas or a reactive gas and ionizing and activating at least one of the gases into plasma. During the process using plasma, RF power is usually generated, and plasma is generated in a reaction space by the generated RF power.

However, in a plasma process at a high temperature, due to thermal deformation of a ground rod connected to a ground electrode in a heating block, a problem occurs in that the impedance of a substrate support unit such as a heating block is changed when plasma is applied to a substrate. This change in impedance causes a change in plasma characteristics on the substrate, and in particular, in the case of a substrate processing apparatus including a plurality of reactors, a problem occurs in that process reproducibility between the reactors is deteriorated.

Korean Patent Publication No. 10-2006-0129566 discloses a susceptor structure that prevents thermal deformation. Paragraph [0013] of the document refers to a problem of thermal deformation of a susceptor that occurs when a temperature of a heater is set higher than a set temperature in order to compensate for heat loss during a PECVD process.

### SUMMARY

One or more embodiments include a substrate processing apparatus capable of minimizing the increase in fatigue of ceramic heating block components (e.g., a characteristic change according to thermal deformation of a ground rod) that may occur in a plasma process at a high temperature.

One or more embodiments include a substrate processing apparatus capable of realizing reproducible processes with minimal process variation between reactors.

Additional aspects will be set forth in part in the description which follows and, in part, will be apparent from the description, or may be learned by practice of the presented embodiments of the disclosure.

According to one or more embodiments, a substrate processing apparatus includes an electrode; and a rod contacting the electrode, wherein the rod includes a first portion having a first coefficient of thermal expansion; and a second portion having a second coefficient of thermal expansion that is less than the first coefficient of thermal expansion.

According to an example of the substrate processing apparatus, the rod may include an alloy between the electrode and the first portion or between the first portion and the second portion, and the alloy may include a material constituting the first portion.

According to another example of the substrate processing apparatus, the first portion may include nickel, and the alloy may include iron, nickel, and cobalt.

According to another example of the substrate processing apparatus, the alloy may include about 50% to about 60% by weight of iron, about 20% to about 30% by weight of nickel, and about 10% to about 20% by weight of cobalt.

According to another example of the substrate processing apparatus, the volume of the first portion may be less than the volume of the second portion.

According to another example of the substrate processing apparatus, the substrate processing apparatus may include an insulating material surrounding the electrode, and a difference between a coefficient of thermal expansion of the electrode and a coefficient of thermal expansion of the insulating material may be less than about 10%.

According to another example of the substrate processing apparatus, the second portion may include the same material as that of the electrode.

According to another example of the substrate processing apparatus, the substrate processing apparatus may further include a metal-coating member configured to prevent the flow of a high-frequency current on a surface of the rod.

According to another example of the substrate processing apparatus, the substrate processing apparatus may further include a welding connection portion arranged between the electrode and the first portion or between the first portion and the second portion.

According to another example of the substrate processing apparatus, the substrate processing apparatus may further include a heat-affected portion formed around the welding connection portion.

According to one or more embodiments, a substrate processing apparatus includes a heating block including aluminum nitride (AlN); an electrode inserted into the heating block and including molybdenum (Mo); and a rod connected to the electrode, wherein the rod includes a first portion welded to the electrode and including nickel (Ni); and a second portion welded to the first portion, and a coefficient of thermal expansion of the second portion may be less than that of the first portion.

According to one or more embodiments, a substrate processing apparatus includes a gas supply unit; a substrate support unit under the gas supply unit; a power supply unit supplying power to a reaction space between the gas supply unit and the substrate support unit; and an exhaust path communicating with the reaction space, wherein the substrate support unit includes an electrode; and a rod connected to the electrode, and the rod includes a first portion having a first coefficient of thermal expansion; and a second portion having a second coefficient of thermal expansion that is less than the first coefficient of thermal expansion.

According to an example of the substrate processing apparatus, one end of the first portion may be connected to the electrode, and the other end of the first portion may be connected to the second portion.

According to another example of the substrate processing apparatus, the first portion may be shorter than the second portion.

According to another example of the substrate processing apparatus, the first portion may include at least one of Ni and tungsten (W).

According to another example of the substrate processing apparatus, the second portion may include at least one of molybdenum (Mo), titanium (Ti), and iron (Fe).

According to another example of the substrate processing apparatus, a surface of the second portion may be coated with rhodium (Rh), silver (Au), and platinum (Pt), or a combination thereof.

According to another example of the substrate processing apparatus, the power supply unit is connected to the gas supply unit and is configured to apply power to the gas supply unit, and the rod may connect the electrode to a ground.

According to another example of the substrate processing apparatus, the power supply unit is connected to the electrode and is configured to apply power to the electrode, and the rod may connect the electrode to the power supply unit.

According to another example of the substrate processing apparatus, the substrate processing apparatus may further include a shield surrounding the rod.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view of a substrate processing apparatus according to embodiments;

FIG. 2 is a view of a substrate processing apparatus according to embodiments;

FIGS. 3 and 4 are views of a substrate support unit (heating block) and a substrate processing apparatus including the same, according to embodiments;

FIG. 5 is a view of a ground rod according to embodiments;

FIG. 6 is a detailed view of a lower structure of a substrate support unit according to embodiments; and

FIG. 7 is a view illustrating an impedance change of an AlN heating block according to a constituent material of a ground rod when a PEALD process is performed at 300° C.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the disclosure will be described in detail with reference to the accompanying drawings.

In this regard, the present embodiments may have different forms and should not be construed as being limited to the descriptions set forth herein. Rather, these embodiments are provided so that the present disclosure will be thorough and complete, and will fully convey the scope of the present disclosure to one of ordinary skill in the art.

The terminology used herein is for the purpose of describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, operations, members, components, and/or groups thereof, but do not preclude the presence or addition of one or more other features, integers, steps, operations, members, components, and/or groups thereof. As used herein, the term “and/or” includes any and all combinations of one or more of the associated listed items.

It will be understood that, although the terms “first”, “second”, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

Embodiments of the disclosure will be described hereinafter with reference to the drawings in which embodiments of the disclosure are schematically illustrated. In the drawings, variations from the illustrated shapes may be expected as a result of, for example, manufacturing techniques and/or tolerances. Thus, the embodiments of the disclosure should not be construed as being limited to the particular shapes of regions illustrated herein but may include deviations in shapes that result, for example, from manufacturing processes.

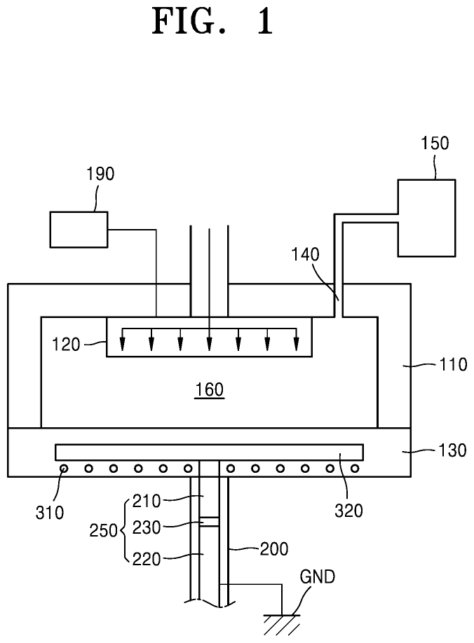

FIG. 1 is a schematic view of a substrate processing apparatus according to embodiments. The substrate processing apparatus may be a deposition (etching) apparatus for performing a deposition (etching) function, and may use plasma to promote a reaction. In this case, a gas supply unit may be formed of a conductive member so that the gas supply unit may function as an electrode when generating plasma.

Referring to FIG. 1, a thin film deposition apparatus may include a partition wall 110, a gas supply unit 120, a substrate support unit 130, and an exhaust path 140.

The partition wall 110 may be a component of a reactor in the thin film deposition apparatus. In other words, a reaction space for the deposition of a thin film on a substrate may be formed by the partition wall 110. For example, the partition wall 110 may include a sidewall and/or an upper wall of the reactor. In the partition wall 110, the gas supply unit 120 having a gas supply channel may be arranged on an upper wall of the reactor. A source gas, a purge gas, and/or a reaction gas may be supplied to a reaction space 160 through the gas supply channel. The gas supplied to the reaction space 160 may be exhausted to an exhaust pump 150 through an exhaust path 140.

The gas supply unit 120 may be on the substrate support unit 130. The gas supply unit 120 may include the gas supply channel described above. The gas supply unit 120 may be fixed to the reactor. For example, the gas supply unit 120 may be fixed to the partition wall 110 through a fixing member (not shown). The gas supply unit 120 may be configured to supply gas to an object to be processed in a reaction space 160. For example, the gas supply unit 120 may be a showerhead assembly.

The gas supply unit 120 may be used as an electrode in a plasma process such as a capacitively coupled plasma (CCP) method. In this case, the gas supply unit 120 may include a metal material such as aluminum (Al). In the CCP method, the substrate support unit 130 may also be used as an electrode, so that capacitive coupling may be achieved by the gas supply unit 120 serving as a first electrode and the substrate support unit 130 serving as a second electrode.

The substrate support unit 130 may be configured to provide a space on which the substrate is seated and to contact a lower surface of the partition wall 110. The substrate support unit 130 may be supported by a body 200, and the body 200 may move up and down and rotate. The substrate support unit 130 is separated from the partition wall 110 or brought into contact with the partition wall 110 by the up and down movement of the body 200 so that the reaction space 160 may be opened or closed.

The substrate support unit 130 may include a heating unit 310 and an electrode 320. The substrate support unit 130 may include an insulating material, and the insulating material may be, for example, aluminum nitride (AlN). The heating unit 310 and the electrode 320 may be surrounded by the insulating material. That is, the heating unit 310 and the electrode 320 may be arranged to be embedded in the insulating material.

The heating unit 310 may be formed to penetrate at least a portion of the substrate support unit 130. The heating unit 310 may be arranged under the substrate seated on the substrate support unit 130 (i.e., inside the substrate support unit 130). The temperature of the substrate and/or the reaction space on the substrate support unit 130 may be increased by heating the heating unit 310. Although the heating unit 310 is shown in FIG. 1 to have a coil shape, the heating unit 310 may have a shape of a plate (e.g., a disc) formed to correspond to a shape of the substrate.

The electrode 320 may penetrate at least a portion of the substrate support unit 130. The electrode 320 may be arranged under a substrate seated on the substrate support unit 130 (i.e., inside the substrate support unit 130). Plasma may be formed in the reaction space 160 by an arrangement structure of the gas supply unit 120 and the electrode 320.

The electrode 320 may be arranged between a substrate to be processed and the heating unit 310. That is, the electrode 320 may be arranged on the heating unit 310 such that radio frequency (RF) power may be transmitted to the substrate without being blocked by the heating unit 310. An insulating material may be arranged between the heating unit 310 and the electrode 320. As described above, the insulating material may include aluminum nitride, and thus the heating unit 310 and the electrode 320 may be surrounded by the aluminum nitride.

The electrode 320 may have a shape corresponding to the shape of the substrate. For example, when the substrate has a shape of a disc, the electrode 320 may also be formed to have a shape of a disc. In some examples, the electrode 320 may have a mesh-like shape.

A power supply unit 190 may be connected to the gas supply unit 120, and thus, power generated by the power supply unit 190 may be supplied to the reaction space 160 through the gas supply unit 120. In more detail, capacitive coupling may be achieved between the gas supply unit 120 and the substrate support unit 130, and plasma may be generated by the capacitive coupling.

The body 200 that is a component of the substrate support unit 130 may include a rod 250. The rod 250 may connect the electrode 320 to a ground GND. Therefore, when power is applied to the gas supply unit 120 by the power supply unit 190, the power may be supplied to the reaction space 160 between the gas supply unit 120 connected to the power supply unit 190 and the electrode 320 connected to the ground GND.

The rod 250 of the body 200 may include a first portion 210 and a second portion 220. The first portion 210 may include a material (e.g., nickel (Ni) and/or tungsten (W)) suitable for welding with the electrode 320. The first portion 210 may have a first coefficient of thermal expansion. For example, the first coefficient of thermal expansion may be greater than a coefficient of thermal expansion of the electrode 320. The second portion 220 may include a material (e.g., Mo, Ti, and/or Fe) having a second coefficient of thermal expansion that is less than the first coefficient of thermal expansion. For example, the second portion 220 may include the same material as that of the electrode 320, and thus the second coefficient of thermal expansion may be substantially the same as the coefficient of thermal expansion of the electrode 320.

For example, the electrode 320 may include molybdenum (Mo). The electrode 320 made of Mo may have an average coefficient of thermal expansion of 4.3×10⁻⁶ at a temperature of about 20° C. to about 315° C. An insulating material of the substrate support unit 130 surrounding the electrode 320 may include AlN. The insulating material made of AlN may have an average coefficient of thermal expansion of 4.5×10⁻⁶ at a temperature of about 20° C. to about 315° C.

As such, a difference between the coefficient of thermal expansion of the electrode 320 and a coefficient of thermal expansion of the insulating material surrounding the electrode 320 may be less than about 10%. By employing materials having similar coefficients of thermal expansion for the electrode 320 and the insulating material, cracks due to thermal expansion in a high temperature process may be prevented. A thermal deformation problem due to a difference in coefficients of thermal expansion may occur between the electrode 320 and the insulating material, or may occur between the electrode 320 and the rod 250.

In order to eliminate the difference in thermal expansion between the electrode 320 and the rod 250, it is preferable to implement the electrode 320 and the rod 250 in an integral structure by employing the same material. However, machining of the electrode 320 and the rod 250 by a milling method in order to implement an integral structure causes a cost problem. When the electrode 320 and the rod 250 are made of parts of the same material and these parts are welded, a stability problem of welding is caused. For example, when welding the electrode 320 made of Mo and the rod 250 made of Mo, a problem occurs in that Mo is oxidized around the welding site. This surface oxidation hinders high-frequency flow.

The substrate processing apparatus according to embodiments is configured such that the rod 250 connected to the electrode 320 includes the first portion 210 having a first coefficient of thermal expansion and the second portion 220 having a second coefficient of thermal expansion that is less than the first coefficient of thermal expansion. As a specific example, when the substrate processing apparatus employs a heating block containing AlN, the electrode 320 including Mo is inserted into the heating block, and the rod 250 connected to the electrode 320 includes the first portion 210 that is welded to the electrode 320 and includes Ni and the second portion 220 that is welded to the first portion 210 and has a coefficient of thermal expansion that is less than the coefficient of thermal expansion of the first portion 210.

As such, by configuring the rod 250 to include the first portion 210 for welding and the second portion 220 having a low coefficient of thermal expansion, a technical effect of preventing an impedance change problem due to thermal deformation while attaining welding stability of a substrate-rod assembly may be achieved.

The first portion 210 of the rod is a portion for welding the rod 250 and the electrode 320, and may include a material that is not oxidized during welding with a component material of the electrode 320. One end of the first portion 210 may be connected to the electrode 320. The other end of the first portion 210 may be connected to the second portion 220.

Because the second portion 220 of the rod is a configuration employed to prevent the impedance change problem, a significant portion of the rod may be implemented as the second portion 220. For example, a length of the first portion 210 may be less than a length of the second portion 220. In addition, a volume of the first portion 210 may be less than a volume of the second portion 220.

Connection between the electrode 320 and the first portion 210 and/or connection between the first portion 210 and the second portion 220 may be achieved by welding. In this case, a welding connection portion 230 arranged between the electrode 320 and the first portion 210 and/or between the first portion 210 and the second portion 220 may be further included. The welding connection portion 230 may include at least one of materials constituting the electrode 320, materials constituting the first portion 210, and materials constituting the second portion 220.

For example, when the welding connection portion 230 is arranged between the electrode and the first portion 210, the welding connection portion 230 may include an alloy having a material constituting the first portion 210. In another example, when the welding connection portion 230 is arranged between the first portion 210 and the second portion 220, the welding connection portion 230 may include an alloy having a material constituting the first portion 210. That is, the electrode 320 and the first portion 210 and/or the first portion 210 and the second portion 220 may be integrated with each other by arranging an alloy containing a material constituting the first portion 210 between the electrode 320 and the first portion 210 and/or between the first portion 210 and the second portion 220 and performing a welding process.

The first portion 210 may include Ni, and the first portion 210 including Ni has excellent weldability to the electrode 320 including Mo. Therefore, in this case, the welding connection portion 230 may include an alloy having Ni, which is a material constituting the first portion 210. For example, the alloy may include iron (Fe), Ni, and cobalt (Co). In another embodiment, the alloy may include about 50% to about 60% by weight of iron, about 20% to about 30% by weight of nickel, and about 10% to about 20% by weight of cobalt. It should be noted that the alloy of this composition ratio has excellent weldability for both Ni and Mo.

In some embodiments, a heat-affected portion may be formed around the welding connection portion 230 (i.e., between the electrode 320 and the first portion 210 and/or between the first portion 210 and the second portion 220). The heat-affected portion is formed during the welding process, and refers to a portion of a base material having a metal structure or properties that are changed by heat. By this change, the heat-affected portion around the welding connection portion 230 may have different properties from those of the electrode 320, the first portion 210, the second portion 220, and/or the welding connection portion 230.

In a further embodiment, the rod 250 may further include a metal-coating member formed on the surface of the rod 250. The metal-coating member may be configured to prevent flow of high frequency currents on the surface of the rod 250. For example, the metal-coating member may include at least one of rhodium (Rh), silver (Au), and platinum (Pt). In some embodiments, the metal-coating member may be formed on a surface of the second portion 220. That is, the surface of the second portion 220 may be coated with Rh, Au, and Pt or a combination thereof.

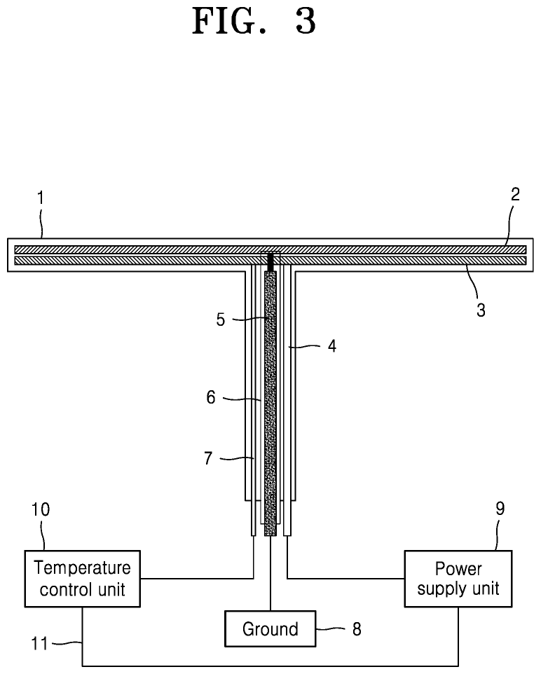

Although not shown in the drawing, the body 200 supporting the substrate support unit 130 may further include a shield (see 6 in FIG. 3) surrounding the rod 250. The shield may block the influence between a signal transmitted to the electrode 320 through the rod 250 and a signal transmitted to the heating unit 310. To this end, the shield may be electrically connected to, for example, the ground GND.

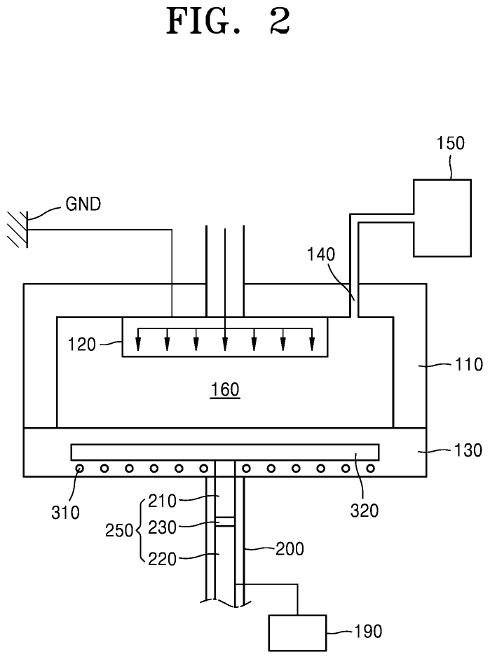

FIG. 2 is a view of a substrate processing apparatus according to embodiments. The thin film deposition apparatus according to the embodiments may be a modification of the substrate processing apparatus according to the above-described embodiments. Hereinafter, repeated descriptions of the embodiments will not be given herein.

Referring to FIG. 2, the power supply unit 190 may be connected to the rod 250. The rod 250 may connect the RF electrode 320 to the power supply unit 190. Therefore, the power supply unit 190 is connected to the RF electrode 320 and power generated by the power supply unit 190 may be applied to the RF electrode 320. The power may be supplied to the reaction space 160 through the RF electrode 320.

On the other hand, the gas supply unit 120 may be connected to the ground GND. Therefore, when power is applied to the RF electrode 320 by the power supply unit 190, the power may be supplied to the reaction space 160 between the RF electrode 320 connected to the power supply unit 190 and the gas supply unit 120 connected to the ground GND.

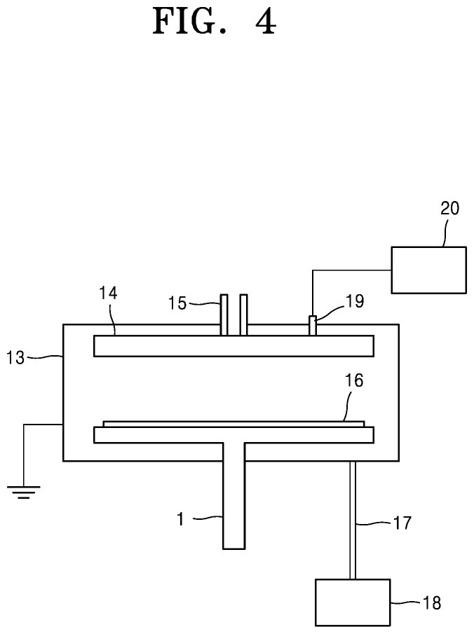

FIGS. 3 and 4 are views of a substrate support unit (heating block) and a substrate processing apparatus including the same, according to embodiments. The thin film deposition apparatus according to the embodiments may be a modification of the substrate processing apparatus according to the above-described embodiments. Hereinafter, repeated descriptions of the embodiments will not be given herein.

Referring to FIGS. 3 and 4, a heating block 1 may be configured to support a substrate 16. The heating block 1 may include a ground electrode 2, a heating unit 3, a power rod 4, a ground rod 5, a shield 6, a thermocouple 7, a ground 8, a power supply unit 9, and a temperature control unit 10. The substrate processing apparatus may include the heating block 1, a reactor 13, a gas distributor 14, a gas inlet 15, an exhaust line 17, an exhaust pump 18, an RF rod 19, and an RF generator 20.

The heating block 1 includes a ceramic material, especially AlN material. The ground electrode 2 and the heating unit 3 are arranged inside the main body of the heating block 1, and the heating unit 3 may be, for example, a heating wire having high electrical resistance. The heating unit 3 is supplied with an electric current from the power supply unit 9 through the power rod 4. One side of the heating unit 3 is in contact with the thermocouple (TC) 7, and the temperature control unit 10 controls current supply of the power supply unit 9 while comparing an actual temperature and a set temperature of the heating unit 3 measured by the thermocouple 7. The ground electrode 2 maintains the same electrical potential as that of the ground 8 through the ground rod 5.

When the ground electrode 2 is connected to an RF power supply instead of the ground 8, for example, an RF power generator, the ground electrode 2 functions as an RF electrode and the ground rod 5 functions as the RF rod 5. When RF power is supplied through the RF rod 5 to the RF electrode 2 in the heating block 1, in order to prevent parasitic plasma from being generated under the heating block 1, the RF rod 5 and the periphery of the RF rod 5 are blocked with the RF signal shield 6. In addition, the RF signal shield 6 also blocks a cross-talk effect in which an RF current affects the surrounding power rod 4 and the power supply unit 9. The RF signal shield 6 is made of aluminum, and the installation of the RF signal shield 6 enables stable current supply and temperature control to the heating unit 3.

When a Ni material constituting the ground rod 5 is used for a long time at a high temperature, it may cause deformation due to thermal expansion, poor connection, or detachment of the ground rod 5. In an embodiment to prevent this problem in advance, an upper end (first portion) of the ground rod 5 in contact with the ground electrode 2 in the heating block 1 is made of the Ni material and connected by welding to the ground electrode 2, and the rest (second portion) of the ground rod 5 except for the upper end thereof is made of a Mo material. The Ni body and the Mo body of the ground rod 5 are connected to each other by welding.

By configuring the ground rod 5 in this way, a deformation problem due to thermal expansion of the ground rod 5 may be prevented. That is, a ceramic heating block in which an impedance change is minimized in a high temperature or plasma process may be implemented. Therefore, the impedance of the heating block during the plasma process may be kept constant.

The Mo body of the ground rod 5 is additionally surface-coated or plated with Rhodium (Rh). By coating the ground rod 5 with Rh, it is possible to prevent surface oxidation and an increase in surface resistance caused by heat of the heating block 1, and to prevent high-frequency flow from being disturbed on a surface of a ground electrode (a skin effect: a high-frequency current flows to a surface of a medium).

In the embodiments of FIGS. 3 and 4, a coefficient of thermal expansion of Ni is 13.4×10⁻⁶/° C. and a coefficient of thermal expansion of Mo is 4.3×10⁻⁶/° C., and thermal expansion of Ni at a high temperature may be compensated for by constructing the ground rod 5 with the materials having different coefficients of thermal expansion. By configuring a ground rod with materials having different coefficients of thermal expansion, there is a technical effect of preventing deformation of the ground rod due to thermal expansion at a high temperature. In addition, in order to minimize deformation of the ground rod 5 due to thermal expansion of Ni, a nickel area is limited to an upper area of the ground rod 5.

In the above embodiment, the upper area, which is a first portion of the ground rod 5, is composed of a Ni body, but in another embodiment, W may be used instead of Ni in the first portion.

In the above embodiment, the remaining area, which is a second portion of the ground rod 5, is composed of a Mo body, but in another embodiment, titanium (Ti) or Fe may be used instead of Mo in the second portion. A surface of the Mo body is coated with Rh, but in another embodiment, the Mo body may be coated with gold (Au) or Pt instead of Rh.

In another embodiment, the ground rod 5 connects the ground electrode 2 to the RF power generator instead of the ground 8 (see FIG. 2). In FIG. 4, RF power is supplied to the upper electrode 14, but in another embodiment, an RF electrode may be additionally installed in the heating block 1 to supply RF power through the heating block 1 as well. That is, the ground rod 5 may function as an RF rod, and the ground electrode 2 may function as an RF electrode, and thus, the heating block 1 may function as a lower electrode (see FIG. 2).

In the embodiment, a surface of the RF rod 5 is plated with Rh to prevent RF current of high-frequency from flowing (skin effect: a high-frequency current flows to a surface of a medium). That is, the RF rod 5 includes an upper portion of a Ni material, the remaining portion of a Mo material coated with Rh, and the RF signal shield 6 surrounding the RF rod 5.

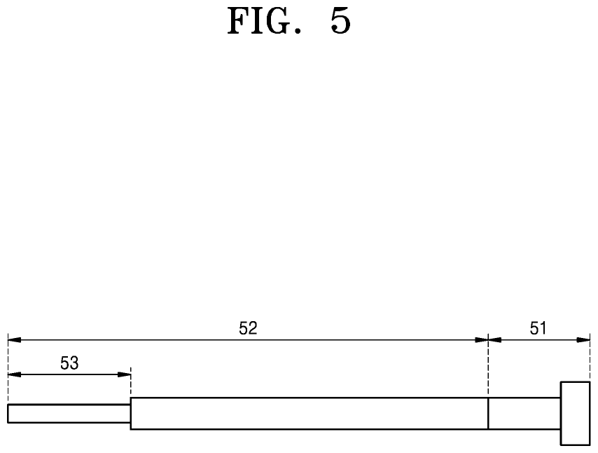

FIG. 5 is a view of the ground rod 5 according to embodiments.

Referring to FIG. 5, the ground rod 5 includes a first portion 51 and a second portion 52 of different materials. The first portion 51 includes Ni, and its end contacts the ground electrode 2 (of FIG. 3) in a heating block. The other end of the first portion 52 is in contact with the second portion 52. The first portion 51 is configured to be shorter than the second portion 52, thereby minimizing deformation of the ground rod due to thermal expansion of the first portion 51 in a high temperature process. The second portion 52 is made of a Mo material, and the surface is coated or plated with Rh. An end 53 of the second portion 52 is inserted into a socket unit (not shown) of a heating block support unit.

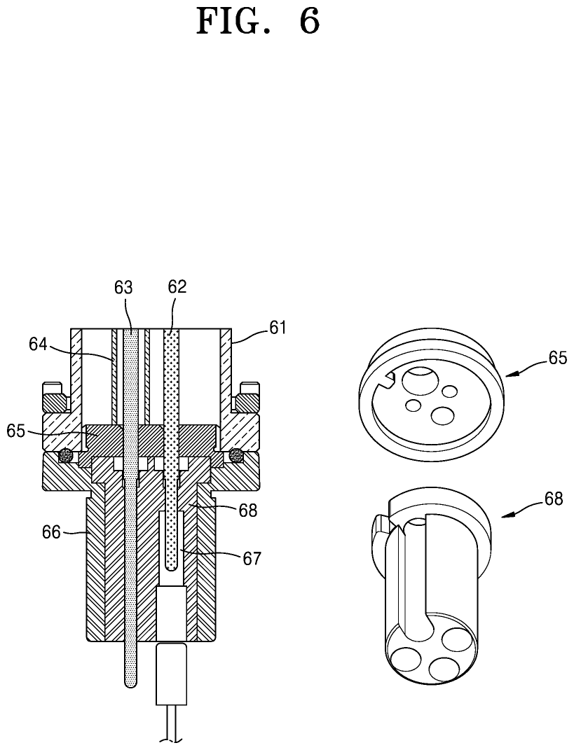

FIG. 6 is a detailed view of a lower structure of a substrate support unit according to embodiments.

Referring to FIG. 6, a lower portion of the substrate support unit (i.e., a heating block support unit) supports an upper portion of the heating block on which a substrate is mounted. In addition, a heating block support has an empty cylindrical shape, and provides a support unit and a path in which a ground rod 63, a shield 64 surrounding the ground rod 63, a power rod 62, and a thermocouple (not shown) are arranged.

A heater block upper portion 61 and a heater block lower portion 66 of the substrate support unit are mechanically or integrally connected to each other using a connection device such as a screw, and an upper rod support 65 and a lower rod support 68 are inserted therein. The upper rod support 65 and the lower rod support 68 have a plurality of through-holes formed therein, and are arranged to correspond to each other. The ground rod 63, the shield 64 surrounding the ground rod 63, the power rod 62, and the thermocouple (not shown) penetrate the through-holes of the upper and lower rod supports 65 and 68. The upper and lower rod supports 65 and 68 fix and support the position of the ground rod 63, the shield 64, the power rod 62, and the thermocouple inside the heater block upper portion 61 and the heater block lower portion 66.

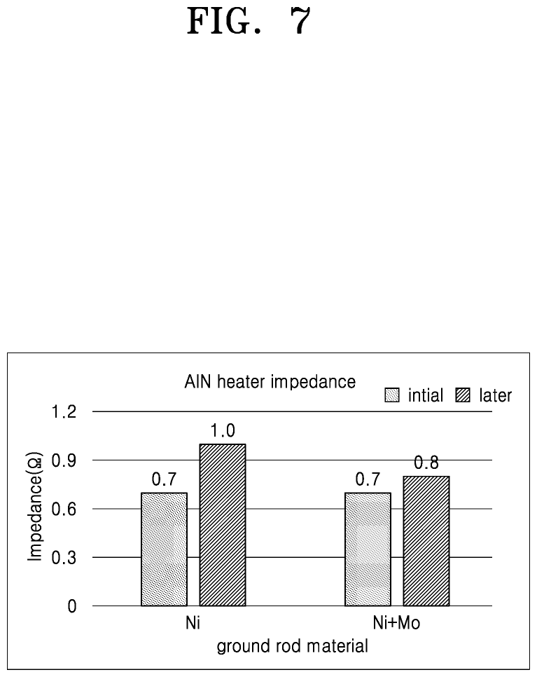

FIG. 7 is a view illustrating an impedance change of an AlN heating block according to a constituent material of a ground rod when a PEALD process is performed at 300° C. Referring to FIG. 7, impedances of the AlN heating block in a case where a ground rod is made of a Ni single material and in a case where a ground rod is made of a Ni and Mo composite material are initially the same at 0.7Ω. However, it can be seen that an impedance change in the AlN heating block increases when the ground rod is made of a Ni single material when the use time increases. This indicates that thermal deformation of the ground rod made of a Ni single material deteriorates the performance of the heating block. This means that the reproducibility of plasma characteristics in a reaction space during the process is lowered.

As a result, as shown in FIG. 7, a heating block having a double-structured ground rod according to embodiments may minimize deformation of the ground rod even when used for a long time in a high temperature plasma process. Accordingly, the impedance change in the heating block is small and a more stable plasma process is possible.

In summary, according to the disclosure, in a high-temperature plasma process, an increase in fatigue of components of a ceramic heating block, for example, a change in characteristics of the ground rod due to thermal deformation, may be minimized. Although the above-described embodiments are applied to a single reactor, the same may also be applied to a plurality of reactors. That is, it is possible to implement a reproducible process with minimal process variation between reactors.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing apparatus comprising:
an electrode; and
a rod contacting the electrode,
wherein the rod comprises:
a first portion having a first coefficient of thermal expansion; and
a second portion having a second coefficient of thermal expansion that is less than the first coefficient of thermal expansion.

2. The substrate processing apparatus of claim 1, wherein
the rod comprises an alloy between the electrode and the first portion or between the first portion and the second portion, and
the alloy comprises a material constituting the first portion.

3. The substrate processing apparatus of claim 2, wherein
the first portion comprises nickel, and
the alloy comprises iron, nickel, and cobalt.

4. The substrate processing apparatus of claim 3, wherein the alloy comprises 50% to 60% by weight of iron, 20% to 30% by weight of nickel, and 10% to 20% by weight of cobalt.

5. The substrate processing apparatus of claim 1, wherein a volume of the first portion is less than a volume of the second portion.

6. The substrate processing apparatus of claim 1, further comprising:
an insulating material surrounding the electrode, and
a difference between a coefficient of thermal expansion of the electrode and a coefficient of thermal expansion of the insulating material is less than 10%.

7. The substrate processing apparatus of claim 1, wherein the second portion comprises the same material as that of the electrode.

8. The substrate processing apparatus of claim 1, further comprising a metal-coating member configured to prevent the flow of a high-frequency current on a surface of the rod.

9. The substrate processing apparatus of claim 1, further comprising a welding connection portion arranged between the electrode and the first portion or between the first portion and the second portion.

10. The substrate processing apparatus of claim 9, further comprising a heat-affected portion formed around the welding connection portion.

11. A substrate processing apparatus comprising:
a heating block comprising aluminum nitride (AlN);
an electrode inserted into the heating block and comprising molybdenum (Mo); and
a rod connected to the electrode,
wherein the rod comprises:
a first portion welded to the electrode and comprising nickel (Ni); and
a second portion welded to the first portion, and
a coefficient of thermal expansion of the second portion is less than a coefficient of thermal expansion of the first portion.

12. A substrate processing apparatus comprising:
a gas supply unit;
a substrate support unit under the gas supply unit;
a power supply unit configured to supply power to a reaction space between the gas supply unit and the substrate support unit; and
an exhaust path configured to communicate with the reaction space,
wherein the substrate support unit further comprises:
an electrode; and
a rod connected to the electrode,
wherein the rod comprises:
a first portion having a first coefficient of thermal expansion; and
a second portion having a second coefficient of thermal expansion that is less than the first coefficient of thermal expansion.

13. The substrate processing apparatus of claim 12, wherein one end of the first portion is connected to the electrode, and the other end of the first portion is connected to the second portion.

14. The substrate processing apparatus of claim 13, wherein the first portion is shorter than the second portion.

15. The substrate processing apparatus of claim 12, wherein the first portion comprises at least one of nickel (Ni) and tungsten (W).

16. The substrate processing apparatus of claim 12, wherein the second portion comprises at least one of molybdenum (Mo), titanium (Ti), and iron (Fe).

17. The substrate processing apparatus of claim 12, wherein a surface of the second portion is coated with at least one of rhodium (Rh), silver (Au), and platinum (Pt), or a combination thereof.

18. The substrate processing apparatus of claim 12, wherein
the power supply unit is connected to the gas supply unit and is configured to apply power to the gas supply unit, and
the rod connects the electrode to ground.

19. The substrate processing apparatus of claim 12, wherein
the power supply unit is connected to the electrode and is configured to apply power to the electrode, and
the rod connects the electrode to the power supply unit.

20. The substrate processing apparatus of claim 12, further comprising a shield surrounding the rod.
